(19) United States
(12) Patent Application Publication
(10) Pub. No.: US 2026/0323862 A1
(43) Pub. Date: Oct. 15, 2026

(54) TABBED ISOLATION MATERIAL DESIGN

(71) Applicant: VERTIV CORPORATION, Westerville, OH (US)

(72) Inventors: Michael Strain, Westerville, OH (US); Carl Caldwell, Cardington, OH (US)

(21) Appl. No.: 19/448,866

(22) Filed: Jan. 14, 2026

Related U.S. Application Data
(60) Provisional application No. 63/785,974, filed on Apr. 9, 2025.

(51) Int. Cl. H05K 7/14

(52) U.S. Cl. CPC H05K 7/1491; H05K 7/1492

(57) ABSTRACT

A guard may be configured to engage an electrical element. The guard may include a front surface that includes a low-friction layer, a back surface configured to be placed against a first surface of the electrical element, wherein the first surface of the electrical element includes conductive fasteners, a first tab configured to engage a first hole of the electrical element; and a second tab configured to engage a second hole of the electrical element.

### CROSS-REFERENCE TO RELATED APPLICATION

The present application claims priority to U.S. Provisional Patent Application Number 63/785,974 filed Apr. 9, 2025, which is incorporated herein by reference in its entirety.

### TECHNICAL FIELD

The present disclosure relates to power systems and, more particularly, to the cabling of power systems.

### BACKGROUND

Data centers and other power-intensive structures rely on power distribution systems to ensure that power is delivered to all components within the structure, such as servers. These power distribution systems may include remote power panels for distributing electrical power. These panels may include sets of cables and busways for routing electrical power.

Currently, many data centers are using higher power loads, partly due to increased AI processing, which places a heavy load on processors. To compensate for increased power load, the power distribution system requires larger cables to carry power and lugs to connect the cables to other electronic components, such as busbars. The increased cable and plug sizes pose a challenge when running cable or assembling cable/busbar components during the panel's commissioning. For example, in panels where neutral cables are pulled tightly behind the phase A cables that contain lugs and bolts, the lugs and bolts of the phase A cables may damage the insulation of the neutral cable during installation, shipping, or service. Therefore, there is a need for a method or device for preventing damage to cable insulation or other components during the cable installation process.

### SUMMARY

Accordingly, the present disclosure is directed to a guard for preventing damage to cabinets and cabinet components when cables are run through the cabinet.

In one or more embodiments, a guard configured to engage an electrical element is disclosed. In embodiments, the guard includes: a front surface including a low-friction material; a back surface configured to be placed against a first surface of the electrical element, wherein the first surface of the electrical element includes conductive fasteners; a first tab configured to engage a first hole of the electrical element; and a second tab configured to engage a second hole of the electrical element.

In one or more embodiments, a system is disclosed. In embodiments, the system includes: an electrical element including: a first surface including conductive fasteners; a first hole; and a second hole; and a guard configured to engage an electrical element. In embodiments, the guard includes: a front surface including a low-friction material; a back surface configured to be placed against the conductive fasteners of the first surface of the electrical element; a first tab configured to engage the first hole of the electrical element; and a second tab configured to engage the second hole of the electrical element.

In one or more embodiments, a method for coupling a guard to a busbar in a cabinet, wherein the busbar comprises conductive fasteners, is disclosed. In embodiments, the method includes providing a guard configured to engage the busbar and cover a portion of the conductive fasteners, the guard including a front surface including a low-friction material; a back surface configured to be placed against the conductive fasteners of a first surface of the busbar; a first tab configured to engage a first hole of the busbar; and a second tab configured to engage a second hole of the busbar; introducing the guard into the cabinet. In embodiments, the method includes aligning the first tab of the guard with the first hole of the busbar. In embodiments, the method includes aligning the second tab of the guard with the second hole of the busbar pulling the first tab of the guard through the first hole of the busbar. In embodiments, the method includes pulling the second tab of the guard through the first opening of the busbar.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the descriptions and the drawings serve to explain the principles of the disclosure.

### BRIEF DESCRIPTION OF DRAWINGS

The numerous advantages of the disclosure may be better understood by those skilled in the art by reference to the accompanying figures.

FIG. 1A illustrates a perspective view of a guard coupled to an electrical element in accordance with one or more embodiments of the disclosure.

FIG. 1B illustrates a view of an underside of the guard in accordance with one or more embodiments of the disclosure.

FIG. 2A illustrates a perspective view of the guard coupled with an electrical element of a busbar arrangement, in accordance with one or more embodiments of the disclosure.

FIG. 2B illustrates a close-up perspective view of the busbar arrangement, wherein a portion of the guard is shown coupled to the electrical element, in accordance with one or more embodiments of the disclosure.

FIG. 3A illustrates a perspective side view of a cabinet containing the busbar arrangement and a connection plate that is configured to receive a neutral wire, in accordance with one or more embodiments of the disclosure.

FIG. 3B illustrates a close-up perspective side view of the cabinet containing the busbar arrangement, in accordance with one or more embodiments of the disclosure.

FIGS. 4A-4C illustrate perspective side views of the cabinet containing the busbar arrangement and the connection plate, in accordance with one or more embodiments of the disclosure.

FIG. 5 illustrates a close-up perspective view of the first tab of the guard engaged with the first opening of the electric element, in accordance with one or more embodiments of the disclosure.

FIG. 6 illustrates a process flow diagram depicting a method for coupling the guard to a busbar of a cabinet or panel, such as wherein the busbar comprises conductive fasteners in accordance with one or more embodiments of the disclosure.

### DETAILED DESCRIPTION

Before explaining one or more embodiments of the disclosure in detail, it is to be understood that the embodiments are not limited in their application to the details of construction and the arrangement of the components or steps or methodologies set forth in the following description or illustrated in the drawings. In the following detailed description of embodiments, numerous specific details may be set forth in order to provide a more thorough understanding of the disclosure. However, it will be apparent to one of ordinary skill in the art having the benefit of the instant disclosure that the embodiments disclosed herein may be practiced without some of these specific details. In other instances, well-known features may not be described in detail to avoid unnecessarily complicating the instant disclosure.

As used herein, a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only and should not be construed to limit the disclosure in any way unless expressly stated to the contrary.

Further, unless expressly stated to the contrary, “or” refers to an inclusive or and not to an exclusive or. For example, a condition A or B is satisfied by any one of the following: A is true (or present), and B is false (or not present), A is false (or not present) and B is true (or present), and both A and B are true (or present).

In addition, the use of “a” or “an” may be employed to describe elements and components of embodiments disclosed herein. This is done merely for convenience and “a” and “an” are intended to include “one” or “at least one,” and the singular also includes the plural unless it is obvious that it is meant otherwise.

Finally, as used herein, any reference to “one embodiment” or “embodiments” means that a particular element, feature, structure, or characteristic described in connection with the embodiment is included in at least one embodiment disclosed herein. The appearances of the phrase “in embodiments” in various places in the specification are not necessarily all referring to the same embodiment, and embodiments may include one or more of the features expressly described or inherently present herein, or any combination or sub-combination of two or more such features, along with any other features which may not necessarily be expressly described or inherently present in the instant disclosure.

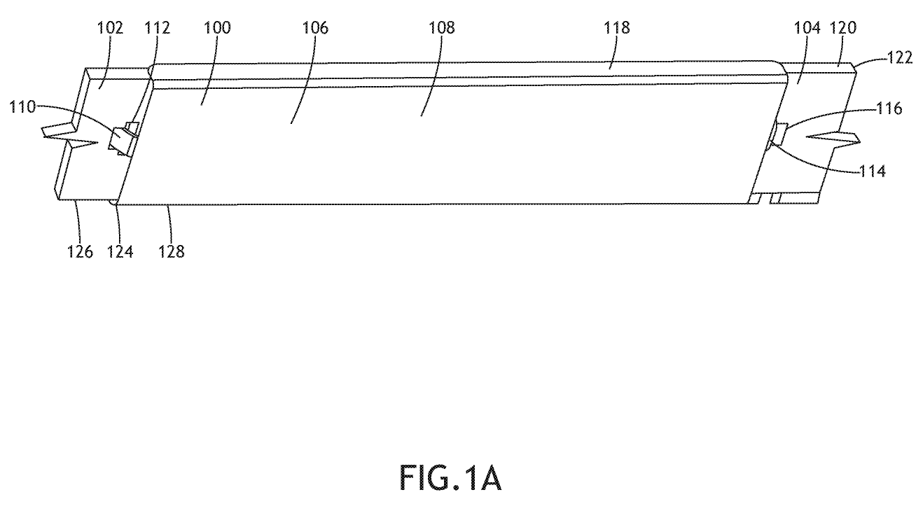

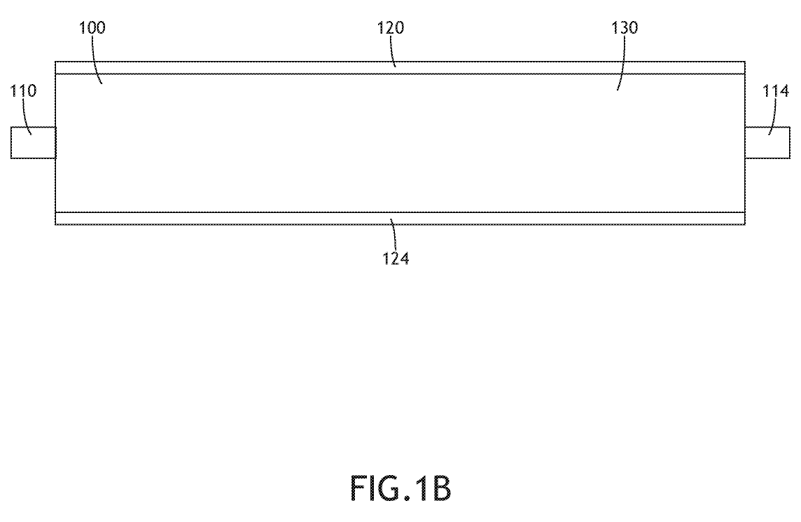

FIGS. 1A-6 illustrate a system, method, and guard for preventing damage to cables or other cabinet componentry when they are being run through a cabinet, in accordance with one or more embodiments of the disclosure.

Embodiments of the present disclosure are directed to a guard configured to bind to a busbar within a power distribution cabinet. The guard latches onto the busbar and covers conductive fasteners (e.g., lugs and bolts) that are used to connect electric cables to the busbar. The front side of the guard facing away from the busbar includes a low-friction material. The guard protects cabinet componentry, such as cables and cable insulation, by providing a smooth surface for when the cables are slid across the busbar during installation (e.g., during running of the cables). The guard is designed so that it can be easily latched onto the busbar without an operator needing to have a straightaway view of the conductive fasteners that are to be covered by the guard (e.g., at a first surface of the busbar).

FIG. 1A illustrates a perspective view of a guard 100 coupled to an electrical element 102 (e.g., a busbar) in accordance with one or more embodiments of the disclosure. The guard 100 is configured to cover a first surface 104 of the electrical element 102 and/or conductive fasteners protruding from the first surface 104. In this manner, the guard 100 acts as a shield that engages the electrical element 102.

The electrical element 102 may be configured as any electrical component that cables or other components are moved against during installation of electrical equipment, such as a power panel or a remote power panel, within a cabinet. For example, an electrical element 102 may include, but not be limited to, a busbar, such as a busbar that is connected to one or more electrical cables. The electrical element 102 may include other components, including, but not limited to, switchboards, feeder panels, cable trays, distribution boards, racks, power distribution units, and conductive rails.

In embodiments, the guard 100 includes a front surface 106. The front surface 106 faces outward when the guard 100 is coupled to the electrical element 102. In embodiments, the front surface 106 includes a low-friction layer 108 or surface. The low-friction layer 108 assists the electrical element 102 and guard 100 in allowing cables and other componentry to glide along an installation path during installation, preventing damage from occurring to the cables and other componentry.

The low-friction layer 108 may include any material or structure that enables the gliding or sliding of cables or other componentry without causing damage, including, but not limited to, plastic. For example, the low-friction layer 108 may include a polycarbonate plastic. For instance, the low-friction layer 108 may include the polycarbonate material, Lexan. The guard 100 may be constructed entirely of the material included in the low-friction layer. For example, the guard 100 may be constructed of plastic. In another example, the guard 100 may be constructed of polycarbonate plastic. In another example, the guard 100 may be constructed of Lexan. In another example, the guard 100 may be constructed of a gas-permeable material, thereby allowing passage of air to cool the electrical element 102.

In embodiments, the guard 100 includes an electrically insulating material. For example, the guard 100 may include an electrically insulating plastic such as polycarbonate plastic, as described above, rubber, and/or any other electrically insulating materials.

In embodiments, the guard 100 includes a first tab 110 configured to engage a first opening 112 of the electrical element 102. For example, the first tab 110 may be designed so that it may be easily pressed into place by an operator, thereby coupling the guard 100 to the electrical element 102. The first tab 110 may be designed to engage with the first opening 112 via an interference fit, a friction fit (e.g., snaps), a press fit, or a transition fit.

In embodiments, the guard 100 includes a second tab 114 configured to engage a second opening 116 on the first surface 104 of the electrical element 102. For example, the second tab 114 may be designed so that it may be easily pressed into place by the operator, thereby coupling the guard 100 to the electrical element 102. The second tab 114 may be designed to engage with the second opening 116 via an interference fit, a friction fit (e.g., snaps), a press fit, or a transition fit.

In embodiments, the guard 100 includes a first side 118 configured to cover a first side 120 of the electrical element 102. For example, the guard 100 may wrap around a first corner 122 of the electrical element 102 to cover at least a portion of the first side 120 of the electrical element 102. The first side 118 of the guard 100 may be designed to fit the electrical element 102 with a friction fit or other fit, further securing the guard 100 to the electrical element 102.

In embodiments, the guard 100 includes a second side 124 configured to cover a second side 126 of the electrical element 102 (the second side 126 of the electrical element 102 is hidden from view in FIG. 1A). For example, the guard 100 may wrap around a second corner 128 of the electrical element 102 to cover at least a portion of the second side 126 of the electrical element 102. The first side 118 of the guard 100 may be designed to fit the electrical element 102 with a friction fit or other fit, further securing the guard 100 to the electrical element 102. For example, the first side 118 of the guard 100 and the second side 124 of the guard may both contribute to providing a fit (e.g., a clamping fit) that further secures the guard 100 to the electrical element 102. In embodiments, the guard 100 and the electrical element 102 are included within a system.

FIG. 1B illustrates a view of an underside of the guard 100 in accordance with one or more embodiments of the disclosure. In embodiments, the guard 100 includes a back surface 130 configured to be placed against the first surface 104 of the electrical element 102. For example, the back surface 130 may be placed against the conductive fasteners of the electrical element 102.

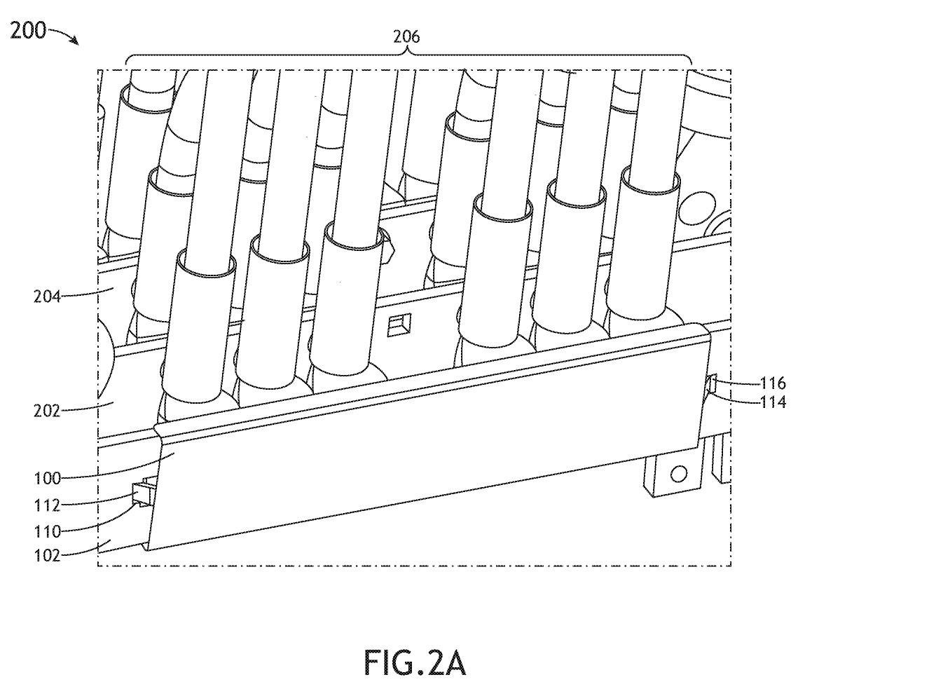

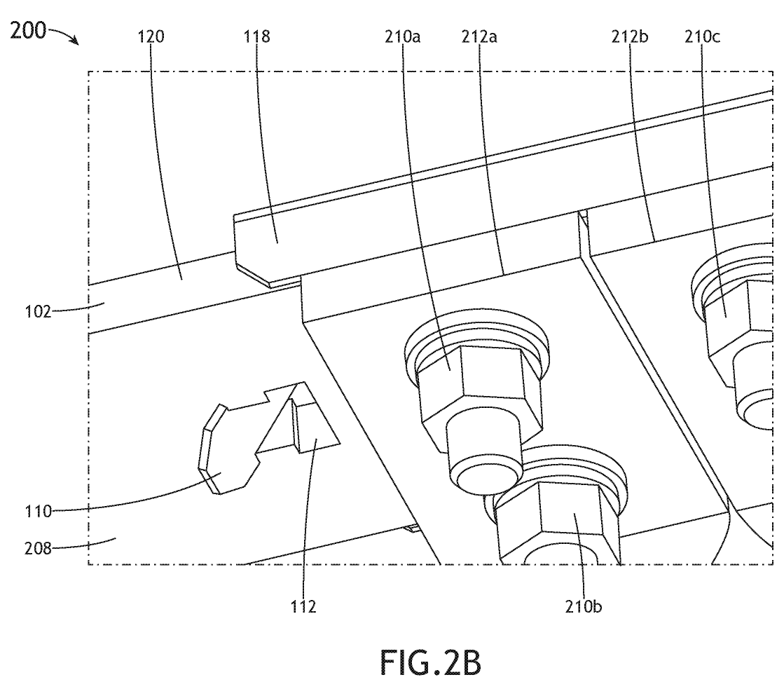

FIG. 2A illustrates a perspective view of the guard 100 coupled with an electrical element 102 (e.g., a busbar) of a busbar arrangement 200, in accordance with one or more embodiments of the disclosure. The busbar arrangement 200 may be positioned inside a cabinet and may include other electrical elements 202, 204, with cable sets 206 attached to the electrical elements 102, 202, 204. The guard 100 is shown coupled to the electrical element 102.

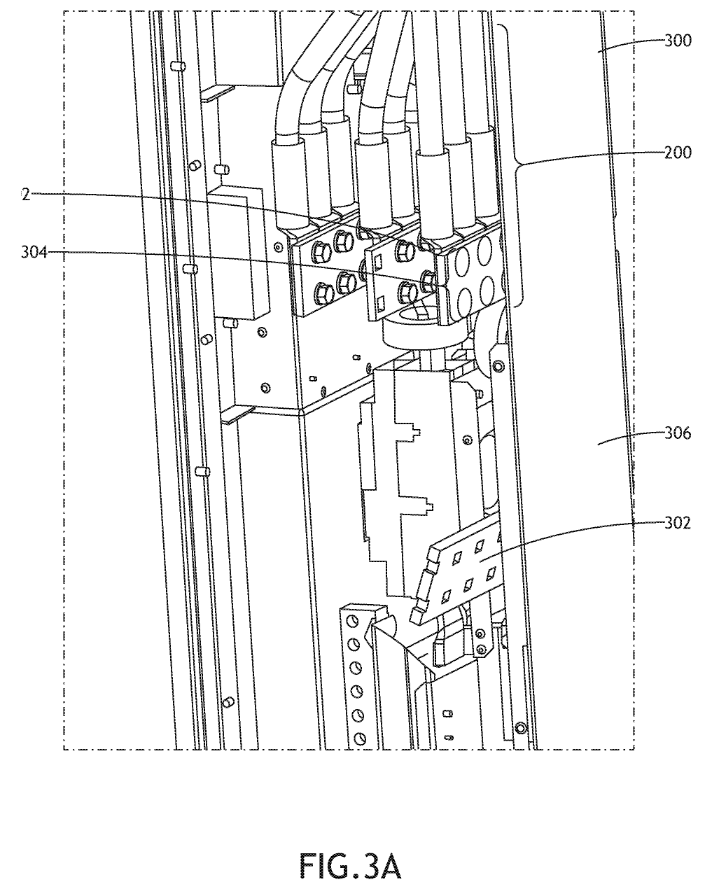

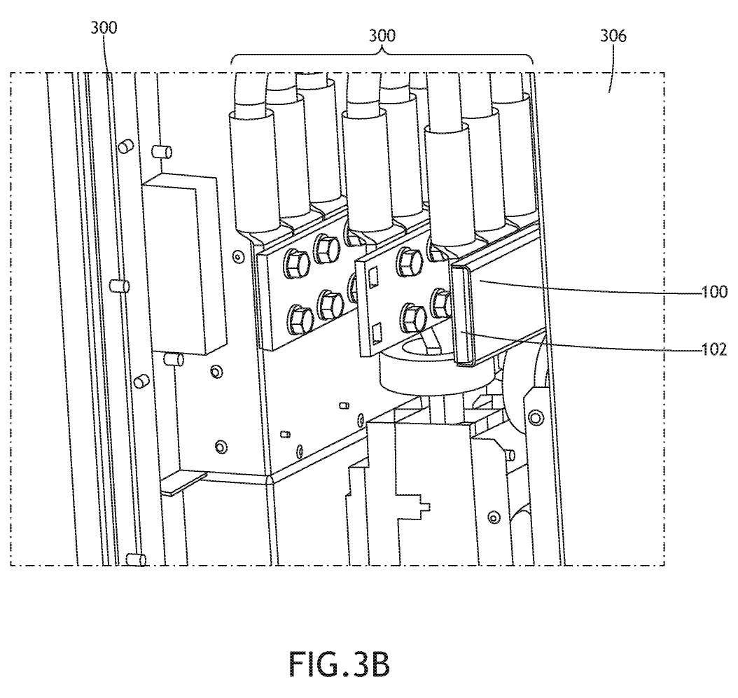

FIG. 2B illustrates a close-up perspective view of the busbar arrangement 200, wherein a portion of the guard 100 is shown mechanically coupled to the electrical element 102, in accordance with one or more embodiments of the disclosure. The first tab 110 of the guard is shown engaged with the first opening 112 of the electrical element 102, with the first tab 110 protruding through to a second surface 208 of the electrical element 102. Also included in FIG. 2B are conductive fasteners 210a, 210b, 210c configured to couple conductive lines (e.g., electrical cables) to the electrical element 102. The conductive fasteners 210a, 210b, 210c, may include any type of fastening devices and/or fastening componentry, including, but not limited to, bolts, nuts, lugs (e.g., compression lugs), clips (e.g., spring clips), rivets, studs, threaded inserts, clamps, pressure connectors, and busbar risers. Brackets 212a, 212bmay also be used as part of the fastening componentry. As shown in FIG. 3A, a portion of the conductive fasteners 210 (e.g., indicated by bolt heads 304 of the conductive fasteners 210) arises from the first surface 104 of the electrical element 102 that is covered by the guard 100, preventing the bolt heads from damaging componentry within the cabinet.

FIG. 3A illustrates a perspective side view of a cabinet 300 containing the busbar arrangement 200 and a connection plate 302 that is configured to receive a neutral wire (neutral wire not shown for clarity), in accordance with one or more embodiments of the disclosure. The busbar arrangement 200 includes the electric element 102 along with a set of bolt heads 304 that face a back panel 306 of the cabinet 300. During assembly of componentry within the cabinet 300, cables are run between the electric element 102 and the back panel 306 to the connection plate 302 during installation. The exposed set of bolt heads 304 risks damaging the cables, such as the cable insulation, as the cables are run to the connection plate 302.

FIG. 3B illustrates a close-up perspective side view of the cabinet 300 containing the busbar arrangement 200, in accordance with one or more embodiments of the disclosure. The guard 100 is shown coupled to the electric element 102, covering the set of bolt heads 304, preventing the set of bolt heads 304 (e.g., conductive fasteners) from damaging cables or other components being run through the cabinet 300 during installation, updating, or repair.

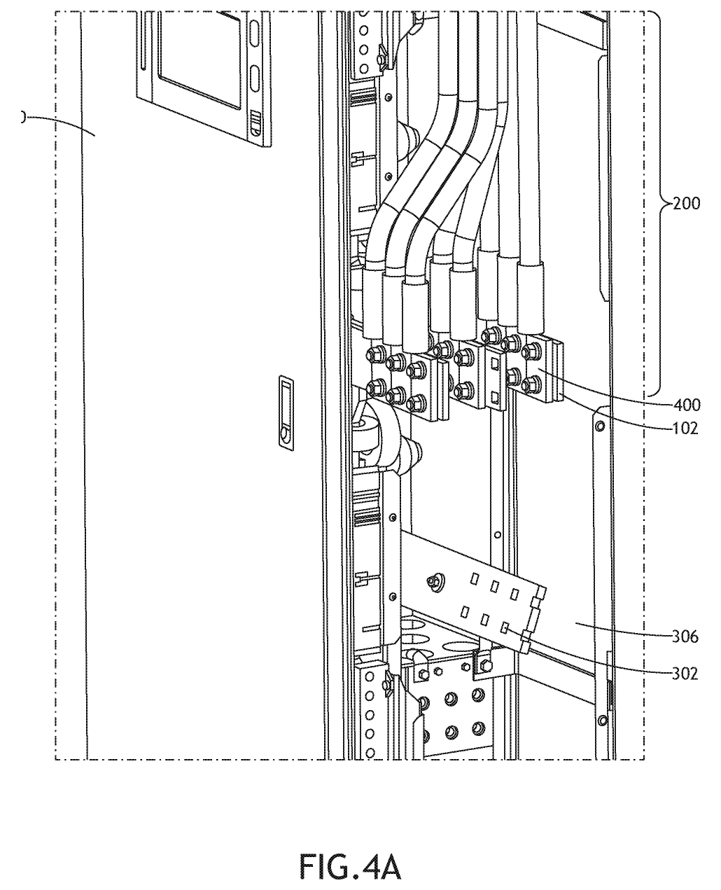

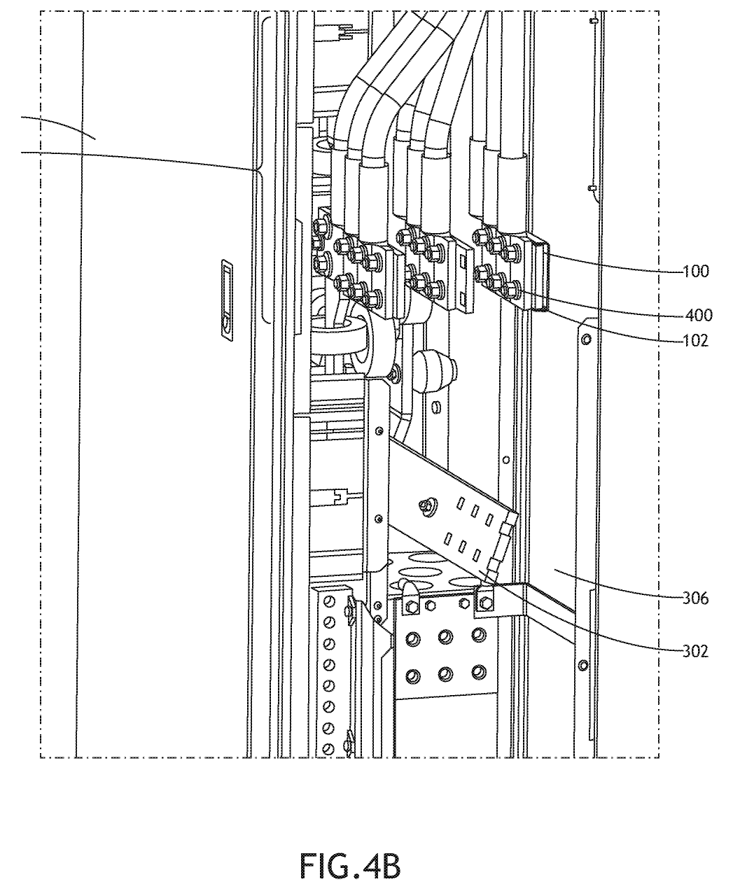

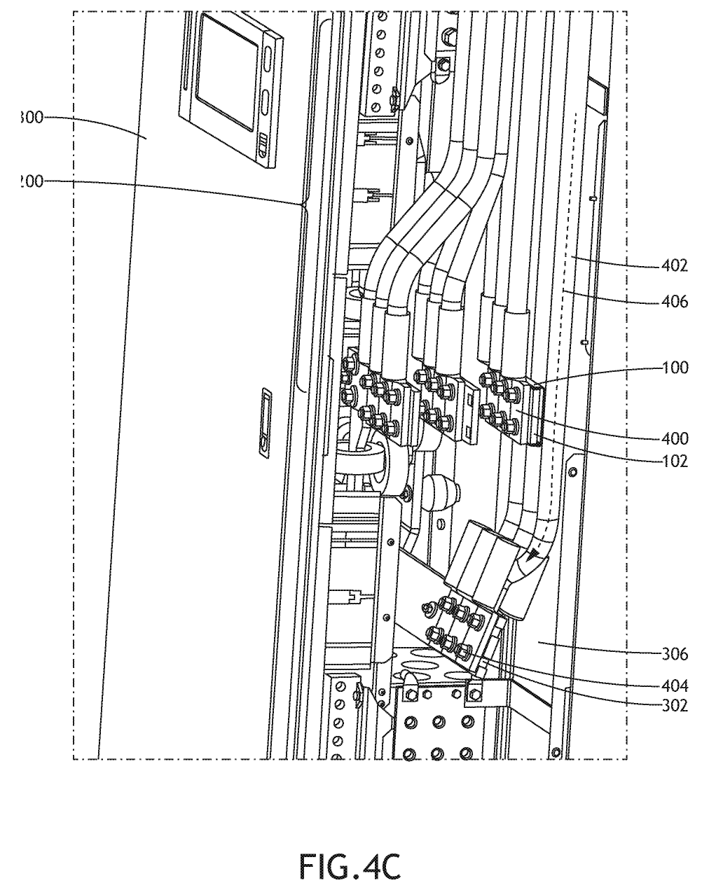

FIGS. 4A-4C illustrate perspective side views of the cabinet 300 containing the busbar arrangement 200 and the connection plate 302, in accordance with one or more embodiments of the disclosure. As in FIGS. 3A and 3B, a busbar (e.g., electric element 102 is coupled to a set of conductive fasteners 400 that could damage cable or other componentry being run between the electric element 102 and the back panel of the cabinet 300, as shown in FIG. 4A

Referring to FIG. 4B, the guard 100 is shown coupled to the electric element 102, covering exposed parts of the set of conductive fasteners 400 that may protrude out to the other side of the electric element 102 (e.g., protruding out from the first surface 104 of the electric element 102). Because of the small space between the electric element 102 and the back panel 306, it would be difficult for an operator to visually line up the guard 100 with the electric element 102. However, the design of the first tab 110 and the second tab 114 allows the operator to easily align the tabs 110, 114 with their respective openings 112, 116. Once the tabs 110, 114 are pressed into the respective openings 112, 116, and/or locked, the guard 100 is installed.

FIG. 4C illustrates the running of a set of neutral cables 402 from above the electrical element 102 to the connection plate 302, in accordance with one or more embodiments of the disclosure. A set of neutral cable conductive fasteners 404 are shown coupled to the connection plate 302. The direction of the running of the set of neutral cables 402 is shown by a dotted arrow 406. The running of the set of neutral cables 402 to the connection plate 302 is performed with the guard 100 installed, preventing the bolt heads 304 of the conductive fasteners 210 from damaging the insulation of the neutral cables 402.

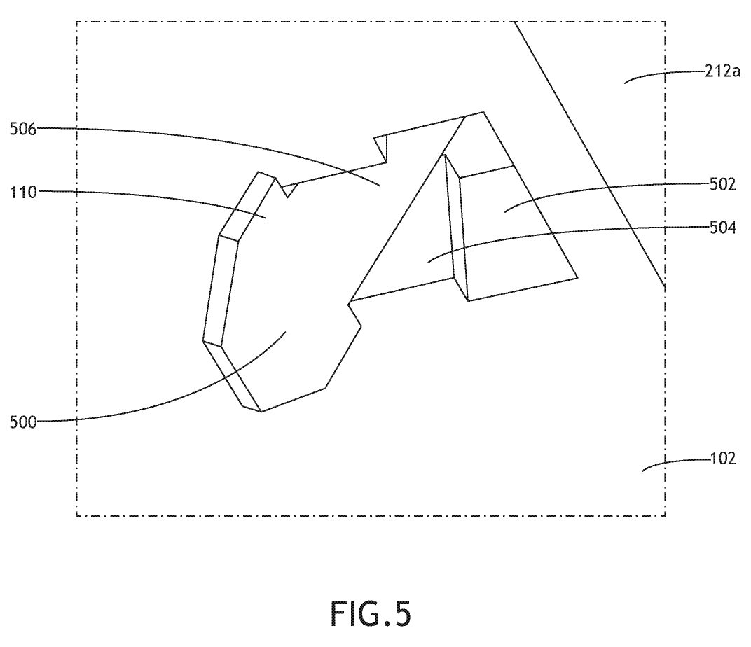

FIG. 5 illustrates a close-up perspective view of the first tab 110 of the guard 100 engaged with the first opening 112 of the electric element 102, in accordance with one or more embodiments of the disclosure.

In embodiments, the first opening 112 includes a T-shaped opening. For example, the first tab 110 may include a wide and flattened paddle section 500 that fits through the top section 502 of the T-shaped opening. Once the paddle section 500 passes through the first opening 112, the first tab 110 slides into the narrow bottom section 504, which accommodates a neck 506 of the first tab 110. The paddle section 500 is then extended through the electrical element 102 and is prevented from disengaging the electrical element 102 through an engagement of the paddle section 500 with the bottom section 504.

The second tab 114 and second opening 116 may be similarly designed. The tabs 110, 114 may be constructed of a spring-like material and structure that, when the tabs 110, 114 are inserted into their respective openings 112, 116, the paddle sections of both tabs 110, 114 spring out into their respective bottom sections 504, locking the guard into place.

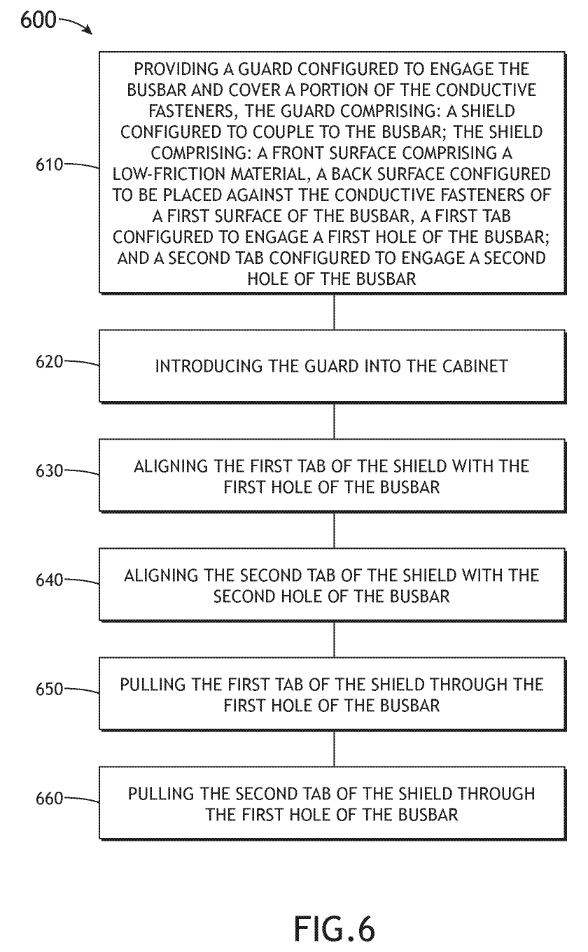

FIG. 6 illustrates a process flow diagram depicting a method 600 for coupling the guard 100 to a busbar (e.g., electric element 102) of a cabinet 300 or panel, wherein the busbar comprises conductive fasteners 210, in accordance with one or more embodiments of the disclosure. For example, method 600 may be used to couple the guard 100 to a busbar in a cabinet 300 configured as a power distribution panel, such as a remote power panel.

In embodiments, the method 600 includes a step 610 of providing a guard 100 configured to engage the busbar and cover at least a portion of the conductive fasteners 210, the guard 100 including: a front surface 106 including a low-friction layer 108 (e.g., including a low-friction material) a back surface 130 configured to be placed against the conductive fasteners 210 of a first surface 104 of the busbar, a first tab 110 configured to engage a first opening 112 of the busbar, and a second tab 114 configured to engage a second opening 116 of the busbar;

In embodiments, the method 600 includes a step 620 of introducing the guard 100 into the cabinet 300. For example, an operator may introduce the guard 100 from the front or side of the cabinet 300, and place and/or align the guard 100 on the first surface 104 of the busbar, at a position where the operator is unable to see straightaway the first surface 104 of the busbar.

In embodiments, the method 600 includes a step 630 of aligning the first tab 110 of the guard 100 with the first opening 112 of the busbar. For example, the operator may slide and align guard 100 along the busbar until the operator either hears a small clicking sound or feels an increase in resistance for sliding the guard 100 along the busbar, indicating that the first tab 110 is aligned with the first opening 112.

In embodiments, the method 600 includes a step 640 of aligning the second tab 114 of the guard 100 with the second opening 116 of the busbar. For example, once the first tab 110 is aligned with the first opening 112, the operator may move the end of the guard 100 with the second tab 114 slightly in one or more directions until the operator either hears a small clicking sound or feels an increase in resistance for sliding the guard 100 along the busbar, indicating that the second tab 114 is aligned with the second opening 116. The alignment of both tabs 110, 114, with their respective openings 112, 116 may occur simultaneously.

In embodiments, method 600 includes a step 650 of pushing the first tab 110 of the guard 100 through the first opening 112 of the busbar. For example, the pushing action may come from the operator pushing the end of the guard 100 that includes the first tab 110 against the busbar with the operator’s fingers. The pushing by the operator’s fingers may be associated with a pulling action by the operator’s arm.

In embodiments, method 600 includes a step 660 of pushing the second tab 114 of the guard 100 through the second opening 116 of the busbar. For example, the pushing action may come from the operator pushing the end of the guard 100 that includes the second tab 114 against the busbar with the operator’s fingers. The pushing by the operator’s fingers may be associated with a pulling action by the operator’s arm. The pushing of the first tab 110 and the second tab 114 may occur simultaneously. After pushing the tabs 110, 114 into their respective openings 112, 116, the guard 100 may be secured into a locked position on the busbar.

The herein-described subject matter sometimes illustrates different components contained within or connected with different other components. It is to be understood that such depicted architectures are merely exemplary and that, in fact, many other architectures can be implemented that achieve the same functionality. In a conceptual sense, any arrangement of components to achieve the same functionality is effectively "associated" such that the desired functionality is achieved. Hence, any two components herein combined to achieve a particular functionality can be seen as "associated with" each other such that the desired functionality is achieved, irrespective of architectures or intermedial components. Likewise, any two components so associated can also be viewed as being "operably connected", or "operably coupled", to each other to achieve the desired functionality, and any two components capable of being so associated can also be viewed as being "operably couplable", to each other to achieve the desired functionality. Specific examples of operably couplable include but are not limited to physically mateable and/or physically interacting components and/or wirelessly interactable and/or wirelessly interacting components and/or logically interacting and/or logically interactable components.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

What is claimed is:

1. A guard comprising:
a front surface comprising a low-friction layer;
a back surface configured to be placed against a first surface of an electrical element, wherein the first surface of the electrical element comprises conductive fasteners;
a first tab configured to engage a first opening of the electrical element; and
a second tab configured to engage a second opening of the electrical element, whereby an engagement of the first tab to the first opening and the second tab to the second opening causes the guard to mechanically couple to the electrical element.

2. The guard of claim 1, wherein the guard comprises a plastic.

3. The guard of claim 2, wherein the guard comprises a polycarbonate plastic.

4. The guard of claim 1, wherein the guard comprises an electrically insulating material.

5. The guard of claim 1, wherein the guard further comprises a first side configured to cover a first side of the electrical element.

6. The guard of claim 5, wherein the guard further comprises a second side configured to cover a second side of the electrical element.

7. The guard of claim 1, wherein the electrical element comprises a busbar.

8. The guard of claim 1, wherein the first tab includes a paddle section and a neck configured to fit through a top section of a T-shaped opening of the first opening, wherein the first tab is configured to slide through a bottom section of the T-shaped opening, wherein the bottom section accommodates the neck, wherein the paddle section is extended through the electrical element and is prevented from disengaging the electrical element through an engagement with the bottom section.

9. The guard of claim 1, wherein the first tab engages the first opening via an interference fit.

10. A system comprising:
an electrical element comprising:
a first surface comprising conductive fasteners;
a first opening; and
a second opening; and
a guard comprising configured to couple to an electrical element, the guard comprising:
a front surface comprising a low-friction material;
a back surface configured to be placed against the conductive fasteners of the first surface of the electrical element;
a first tab configured to engage the first opening of the electrical element; and
a second tab configured to engage the second opening of the electrical element.

11. The system of claim 10, wherein the guard comprises a polycarbonate plastic.

12. The system of claim 10, wherein the guard comprises an electrically insulating component.

13. The system of claim 10, wherein the guard further comprises a first side configured to cover a first side of the electrical element.

14. The system of claim 13, wherein the guard further comprises a second side configured to cover a second side of the electrical element.

15. The system of claim 10, wherein the electrical element comprises a busbar.

16. The system of claim 10, wherein the first tab includes a paddle section and a neck configured to fit through a top section of a T-shaped opening of the first opening, wherein the first tab is configured to slide through a bottom section of the T-shaped opening, wherein the bottom section accommodates the neck, wherein the paddle section is extended through the electrical element and is prevented from disengaging the electrical element through an engagement with the bottom section.

17. The system of claim 10, wherein the first tab engages the first opening via an interference fit.

18. A method for coupling a guard to a busbar in a cabinet, wherein the busbar comprises conductive fasteners, the method comprising:
providing a guard configured to engage the busbar and cover a portion of the conductive fasteners, the guard comprising:
a front surface comprising a low-friction material;
a back surface configured to be placed against the conductive fasteners of a first surface of the busbar;
a first tab configured to engage a first opening of the busbar; and
a second tab configured to engage a second opening of the busbar;
introducing the guard into the cabinet;
aligning the first tab of the guard with the first opening of the busbar;
aligning the second tab of the guard with the second opening of the busbar;
pushing the first tab of the guard through the first opening of the busbar; and
pushing the second tab of the guard through the second opening of the busbar.

19. The method of claim 18, wherein the method is performed by an operator without the operator having a view of the first surface of the busbar.

20. The method of claim 18, wherein the first tab includes a paddle section and a neck configured to fit through a top section of a T-shaped opening of the first opening, wherein the first tab is configured to slide through a bottom section of the T-shaped opening, wherein the bottom section accommodates the neck, wherein the paddle section is extended through the busbar and is prevented from disengaging the busbar through an engagement with the bottom section.
